(19) United States
(12) Patent Application Publication
(10) Pub. No.: US 2018/0290884 A1
(43) Pub. Date: Oct. 11, 2018

(54) NANO-ENGINEERED SURFACES FOR ACTIVELY REVERSIBLE AND REUSABLE DRY ADHESION SYSTEMS AND RELATED METHODS

(71) Applicant: Metis Design Corporation, Boston, MA (US)

(72) Inventor: Seth S. Kessler, Newton, MA (US)

(21) Appl. No.: 15/950,781

(22) Filed: Apr. 11, 2018

Related U.S. Application Data
(60) Provisional application No. 62/484,140, filed on Apr. 11, 2017.

(51) Int. Cl. B81C 1/00; C01B 32/168

(52) U.S. Cl. CPC B81C 1/00174; B82Y 30/00; C01B 32/168

(57) ABSTRACT

An actively reversible and reusable dry adhesion system, and related methods for using the same, may comprise a first plurality of nanoparticles, e.g., carbon nanotubes, formed on a first substrate that may be selectively reconfigured in response to an active stimulus, e.g., electrical current, temperature gradient, magnetism, etc.; a second plurality of nanoparticles, e.g., carbon nanotubes, formed on a second substrate that may be selectively reconfigured in response to the active stimulus; and a switch or button that may be operably connected to the first and second substrates. The switch or button may be configured to selectively apply the active stimulus. When the switch or button is activated, the first and second pluralities of nanoparticles may interlock to adhere the first substrate to the second substrate. The dry adhesion system may form an interlocking fastener on a nanoscale, and may be reversible and reusable.

### CROSS-REFERENCE TO RELATED APPLICATIONS

This application claims the benefit of priority under 35 U.S.C. § 119(e) of U.S. Provisional Patent Application No. 62/484,140, which was filed on Apr. 11, 2017, the entirety of which is herein incorporated by reference.

### TECHNICAL FIELD

The present disclosure relates to nano-engineered surfaces and, in particular, to nanoparticles (e.g., carbon nanotubes) grown on substrates for a variety of industrial uses, wherein the nanoparticles achieve customizable positioning into multiple configurations (e.g., custom geometries, custom orientations, etc.) based on selective application of an active stimulus (e.g., electrical, thermal, magnetic, mechanical, etc.). In some instances, aspects of the present disclosure relate to systems, methods, and apparatus for reversible and reusable dry adhesion comprising nanoscale structural patterns including carbon nanotube forests to form nanoscale controllable interlocking fasteners. According to aspects of the disclosure described herein, the interlocking fasteners may be controllable similar to a shape memory alloy or a shape memory polymer, and may be releasably entangled or untangled in response to the active stimulus.

### BACKGROUND

Nanoparticles are particles between 1 and 100 nanometers (nm) in size with a surrounding interfacial layer. The interfacial layer may be an integral part of nanoscale matter, which may fundamentally affect its properties. The interfacial layer may consist of ions, inorganic and organic molecules. Carbon nanotubes, or CNTs, are one example of a nanoparticle.

CNTs are allotropes of carbon with a cylindrical nanostructure. CNTs contain cylindrical carbon molecules with various properties applicable to nanotechnology, electronics, optics, mechanical arts, and other fields of material science and technology. CNTs are known for their exceptional strength at the atomic level and stiffness as certain nanotubes have been formed with length-to-diameter ratios of up to 132,000,000:1, significantly larger than many other materials. CNTs may be used to enhance traditional composite laminates. CNTs the ability to improve impact resistance and fracture toughness. CNTs possess a variety of superior properties, including: mechanical, electrical, and thermal. Generally, CNTs are formed as a single-walled carbon nanotube (SWNT) or as multiple-walled carbon nanotube (MWNT). SWNTs can be conceptualized as wrapping a one-atom-thick layer of graphic called graphene into a seamless cylinder. Most SWNTs have a diameter of close to about 1 nanometer (nm), with a tube length that can be many thousands of times larger (e.g., SWNT with lengths up to orders of centimeters have been produced). In contrast, MWNTs comprise multiple layers of graphite rolled upon themselves to form a tube shape. When materials comprising either SWNT or MWNT architectures are employed, such materials may produce robust nano-engineered components.

Using either chemical vapor deposition (CVD), atomic layer deposition (ALD), or any other suitable CNT manufacturing process, a plurality of CNTs may be grown on a substrate (e.g., thermally-oxidized silicon wafers), which may be referred to as a CNT forest. CNTs grown by CVD from a high-density arrangement of catalyst nanoparticles on a substrate are known to self-organize into vertically aligned assemblies often called CNT forests. CNT forests may comprise CNTs having a unique single or multi-walled structures that may be grown on various substrates through a variety of catalyzed reactions. Both the density and rate of CNT forest growth from a supported catalyst (e.g., Fe/Al2O3, 1/10 nm) may be influenced by the material immediately beneath the support. Moreover, these CNTs may be engineered with high thermal and electrical conductivities.

### SUMMARY

In accordance with some embodiments of the present disclosure, an exemplary actively reversible and reusable dry adhesion system including a CNT forest formed on a substrate, wherein one or more fields or active stimulus (e.g., thermal, electrical current, magnetic, mechanical) may be applied to the CNT forest to change the shape, geometry, and/or configuration of the CNT forest. CNT forests may be formed on two or more adhesion materials (e.g., substrates). A CNT forest formed on a first dry adhesion material may interlock and entangle with a CNT forest formed on a second dry adhesion material. A portion or the entire CNT forest may be capable of being selectively reconfigured in shape in response to selectively applying an active stimulus (e.g., a field of thermal, magnetic, electrical, mechanical energy, etc.). In some embodiments, and in response to the active stimulus, the dry adhesion system may releasably engage (e.g., entangle) or disengage (e.g., untangle).

In accordance with some embodiments of the present disclosure, an exemplary dry adhesion system is provided. The dry adhesion system may include nanoscale fastening, and may be actively reversible and reusable. The dry adhesion system may comprise a first plurality of nanoparticles formed on a first substrate and capable of changing from a first shape to a second shape in response to an active stimulus; a second plurality of nanoparticles formed on a second substrate and capable of changing from a first shape to a second shape in response to the active stimulus; and a switch that may be operably connected to the first and second substrates and configured to selectively apply the active stimulus, wherein when the switch is activated, the first and second pluralities of nanoparticles may change from their respective first shape to their respective second shape to interlock the first substrate to the second substrate, and wherein when the switch is deactivated, the first and second pluralities may change from their respective second shape to their respective first shape to release the first substrate from the second substrate.

In accordance with some embodiments of the present disclosure, another exemplary dry adhesion system is provided. The dry adhesion system may include nanoscale fastening, and may be actively reversible and reusable. The dry adhesion system may comprise a first plurality of nanoparticles formed on a first substrate and capable of changing from a first shape to a second shape in response to an active stimulus; a second plurality of nanoparticles formed on a second substrate, wherein the first and second pluralities are configured to entangle to lock the first substrate with the second substrate; and a switch that may operably connected to the first substrate and configured to selectively apply the active stimulus, wherein when the switch is activated, the first plurality of nanoparticles may change from their respective first shape to their respective second shape to unlock the first substrate from the second substrate.

In accordance with some embodiments of the present disclosure, an exemplary method for dry adhesion is provided. The method may include actively reversible and/or reusable dry adhesion. The method may comprise the steps of configuring a first plurality of nanoparticles formed on a first substrate with a second plurality of nanoparticles formed on a second substrate, wherein the first and second pluralities of nanoparticles are capable of changing from a first shape to a second shape in response to an active stimulus; activating a switch operably connected to the first and second substrates and configured to selectively apply the active stimulus, wherein when the switch is activated, the first and second pluralities of nanoparticles change from their respective first shape to their respective second shape to interlock the first substrate to the second substrate; and deactivating the switch, wherein when the switch is deactivated, the first and second pluralities of nanoparticles change from their respective second shape to their respective first shape to release the first substrate from the second substrate.

In accordance with some embodiments of the present disclosure, another exemplary method for dry adhesion is provided. The method may include actively reversible and/or reusable dry adhesion. The method may comprise the step of activating a switch configured to selectively apply an active stimulus, wherein the switch is operably connected to a first plurality of nanoparticles formed on a first substrate, wherein the first plurality nanoparticles are capable of changing from a first shape to a second shape in response to the active stimulus, wherein when the switch is activated, the first plurality of nanoparticles change from their respective first shape to their respective second shape to unlock the first plurality of nanoparticles of the first substrate from a second plurality of nanoparticles formed on a second substrate.

Other objects and features will become apparent from the following detailed description considered in conjunction with the accompanying drawings. It is to be understood, however, that the drawings are designed as an illustration only and not as a definition of the limits of the invention.

### BRIEF DESCRIPTION OF THE DRAWINGS

The accompanying drawings, which are incorporated in and constitute a part of this specification, illustrate exemplary embodiments of the present disclosure and together with the description, serve to explain the principles of the disclosure.

FIG. 1 illustrates an enlarged, perspective view of an exemplary carbon nanotube (CNT) microstructure design of an exemplary nanoscale dry adhesion system, according to aspects of the present disclosure;

FIGS. 2A-2C depict perspective views of an exemplary application of the nanoscale dry adhesion system of FIG. 1, according to aspects of the present disclosure;

FIGS. 3A-3C depict perspective views of another exemplary application of the nanoscale dry adhesion system of FIG. 1, according to aspects of the present disclosure;

FIGS. 4A-4C depict perspective views of another exemplary application of the nanoscale dry adhesion system of FIG. 1, according to aspects of the present disclosure;

FIG. 5 depicts a perspective view of an exemplary CNT curved pillar of a nanoscale dry adhesion system, according to aspects of the present disclosure;

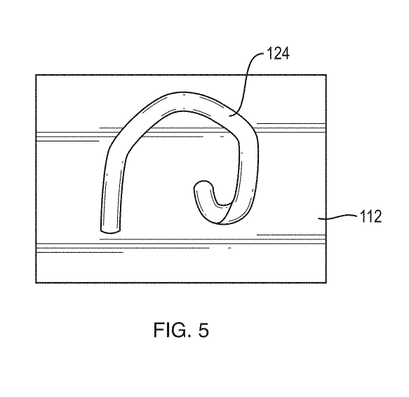

FIG. 6 depicts a flowchart of an exemplary process of operating a dry adhesion system in accordance with some embodiments of the present disclosure; and

FIG. 7 depicts an exemplary electrode array in accordance with some embodiments.

### DETAILED DESCRIPTION OF CERTAIN EXEMPLARY EMBODIMENTS

Reference will now be made in detail to certain exemplary embodiments according to the present disclosure, certain examples of which are illustrated in the accompanying drawings. Wherever possible, the same reference numbers will be used throughout the drawings to refer to the same or like parts.

In this application, the use of the singular includes the plural unless specifically stated otherwise. In this application, the use of “or” means “and/or” unless stated otherwise. Furthermore, the use of the term “including”, as well as other forms, such as “includes” and “included”, is not limiting. Any range described herein will be understood to include the endpoints and all values between the endpoints.

The section headings used herein are for organizational purposes only and are not to be construed as limiting the subject matter described. All documents, or portions of documents, cited in this application, including but not limited to patents, patent applications, articles, books, and treatises, are hereby expressly incorporated by reference in their entirety for any purpose.

As used herein “substrate” may refer to any substance or layer on which nano-engineered surfaces (e.g., CNT pillars, CNT forests, or any other suitable nanoparticle) may grow. In some aspects of the present disclosure, nano-engineered surfaces may be grown on a flexible polymer (e.g., polyimide) and then transferred to a rigid substrate (e.g., silicon, alumina, etc.) upon which the substrate may be processed for CNT growth under an atmospheric pressure CVD recipe. It should also be appreciated that CNT pillars, CNT forests, or any other suitable nanoparticle may be engineered, formed, fabricated, or manufactured via ALD, CVD, laser-based electrostatic printing process, or any other suitable process for growing carbon nanotubes.

As used herein “nanoparticles” may refer to any particle or structure grown on a substrate between 1 and 100 nanometers (nm) in size. It should be appreciated that any nanoparticle may be grown, formed, engineered, fabricated, or otherwise manufactured on a suitable substrate for purposes of forming nano-engineered surfaces having interlocking features suitable for reversible and reusable dry adhesion. In many aspects of the present disclosure, exemplary nanoparticles include CNTs or CNT forests. In many aspects of the present disclosure, the nanoparticles as taught herein may be coated or surface treated in order to control the coated nanoparticles with a selective application of an active stimulus (e.g., electrical current, electrical field, thermal gradient, heat, magnetism, magnetic field, etc.). In some embodiments, the active stimulus may refer to an energy field (e.g., electrical field).

As used herein “active” or “actively” may refer to releasably engaging (e.g., entangling) and/or disengaging (e.g., untangling) reversible and reusable dry adhesion materials in response to the aforementioned active stimulus or energy field. Reversible and reusable dry adhesion materials may comprise nano-engineered surfaces that may include exemplary nanoparticles as taught herein. Exemplary nanoparticles, as taught herein, may be controlled in order to entangle or untangle dry adhesion materials. Moreover, throughout the present disclosure, the aforementioned active stimulus may be referred to as a field.

As used herein “nano-engineered” or “nano-fabricated” may refer to the production of materials with functional elements typically at a submicron scale, and can refer to processes such as nanolithography, ion etching, laser nanomachining, nanoimprinting, molecular self-assembly, electron-beam lithography, and other processes known in the art of nanotechnology.

As taught herein, CNTs and CNT forests may be used for a variety of dry adhesion applications or functions. Conventionally, adhesion systems require the use of heat, ultrasonic energy, or a two-part liquid substance in order for permanent chemical bonding to occur. In dry adhesion systems, there is no chemical bonding, but rather mechanical interlocking causing surfaces to adhere together. Reversible dry adhesion systems may include dry adhesion materials that may be initially adhered together temporarily, and may then be subsequently separated from each other. Reusable dry adhesion systems may permit the dry adhesion materials to be used in a reversible manner without breakage of the dry adhesion materials.

Macroscale dry adhesion systems, for example VELCRO® fasteners (Velcro Industries B.V., the Netherlands), may be reversible and reusable, but may be limited in their strength of adhesion and may also be limited in their use and re-use. Macroscale dry adhesion systems, for example VELCRO® fasteners, may include hooks and loops that are visible to the human eye or have a tactile feel when touched. In comparison, and as taught herein, the dry adhesion systems are on the micro or nano scale. These microscale and nanoscale dry adhesion systems do not have elements visible to the human eye, and, in some embodiments, do not have a tactile feel when touched by a human.

Various aspects of the present disclosure take advantage of micro-scale top-down lithographic patterning in conjunction with nanoscale self-organization, which enable fabrication of nanoparticles made up of aligned CNTs over a large-area substrate. It can be appreciated that other suitable CNT manufacturing processes may be used to achieve large-area fabrication of freeform nanostructures comprising CNTs. During the fabrication of CNTs or CNT forests, it can be appreciated that the CNTs, or other suitable nanostructures, may be formed on a substrate in a variety of shapes and configurations, such as, e.g., curved, folded, twisted, square-shaped, rectangular-shaped, star-shaped, ellipsoidal, circular, disc-shaped, pillars, tubes, notches, rivets, ribs, etc. Exemplary embodiments of freeform nanoparticles are described and depicted further within the present disclosure. In examples described herein, and according to aspects of the present disclosure, a dry adhesion system comprising a nanoscale interlocking fastener may be adapted for fastening an article, composite material, or composite part to itself, to another object, or, for joining two or more components of the article. Various applications of using such a nanoscale interlocking fastener will be described hereto within the present disclosure.

Various aspects of the present disclosure relate to nanoscale manufactured surfaces having nanoparticles used as interlocking fasteners (e.g., actively reversible and reusable dry adhesion systems). In some embodiments described herein, the nanoscale interlocking fastener(s) may be configured to be actively reversible and reusable. In an exemplary embodiments, the nanoparticles may be coated with a surface treatment or a coating, as taught herein. In some embodiments, the coating or surface treatment may also be applied to one or more surfaces of the associated substrate on which the nanoparticle is formed. In an exemplary embodiment, the coated nanoparticles may be formed on one or more adhesion materials, for example, a first and second substrate, or first and second adhesive materials, etc. In some embodiments, nanoparticles formed on the first substrate may be coated or surfaced treated with a coating or treatment that is different from the coating or treatment applied to the nanoparticle formed on the second substrate. The surface treatments and/or coatings may be responsive to an active stimulus (e.g., thermal, electrical, magnetic, etc.) as taught herein. In an exemplary embodiment, such coatings or surface treatments may be temperature sensitive. The active stimulus may be controlled, adjusted, activated, or selectively engaged by a user. The active stimulus may be activated by a controller (e.g., an electronic controller connected to a battery or power source). In some embodiments, the active stimulus may be activated and deactivated with a switch or button connected to a battery or other suitable power source.

In some embodiments, when activated, and in the presence of the active stimulus as taught herein (e.g., the user activates the active stimulus), the coated nanoparticles may be controlled to change their shape from a respective first shape to a respective second shape. In doing so, the coated nanoparticles of a respective first substrate may interlock or adhere with the coated nanoparticles of a respective second substrate to achieve active dry adhesion as taught herein (e.g., nanoscale interlock fastening). It can be appreciated that the first and second substrates may adhere to each other with a peel and shear strength that may meet or exceed that of traditional joining methods (e.g., bonding, welding, etc.).

In some embodiments, when deactivated, and when the aforementioned active stimulus is removed (e.g., the user deactivates the active stimulus), the coated nanoparticles may be controlled to change their shape from the respective second shape back to their respective first shape. In doing so, the coated nanoparticles from the respective first substrate may untangle (e.g., un-interlock) from the respective second substrate to achieve actively reversible and reusable dry adhesion as taught herein. As the coated nanoparticles return to their respective first shape when the active stimulus is removed or not present, the dry adhesion system may achieve active reversibility and reusability.

In some embodiments, when deactivated, and when the aforementioned active stimulus is removed (e.g., the user deactivates the active stimulus), the coated nanoparticles may maintain their shape or state.

In some embodiments, initial active dry adhesion of the two substrates may occur via a mechanical load (e.g., a user press fitting two adhesive materials together to interlock the coated nanoparticles). In this example, an active stimulus may be selectively applied to either one or both the first and second substrates so that the respective coated nanoparticles formed on either the first and/or second substrate may change shape. In doing so, the coated nanoparticles may untangle to release the first substrate from the second substrate as taught herein. In such an example, the active dry adhesion may be reversible and reusable. In situations where the coated nanoparticles are damaged permanently (e.g., repeated changes in shape), the active dry adhesion system may be reversible, but not reusable.

The actively reversible and reusable dry adhesion system as taught herein may include nanoscale interlocking fasteners comprising a high peel strength. In such an example, the nanoscale interlocking fastener may be separated (e.g., reversible as two adhesion materials are pulled apart) with minimal or zero force. In an exemplary embodiment, the nanoscale interlocking fastener may be silent when separation occurs (e.g., a first material is pulled apart from a second adhesive material), in contrast to macroscale interlocking fasteners, for example, VELCRO® fasteners, which may emit noise as the fastener is released.

In some embodiments, by controlling the orientation or shape of the nanoparticles formed, which may be affixed onto a surface of a material, individual nanoparticles or an entire surface of nanoparticles may be controlled to form an interlocking fastener on a nanoscale. For example, in an exemplary embodiment, an electric current may be applied to the CNTs (e.g., individual CNTs or CNT forests) taught herein in order to heat up the CNTs. Once sufficiently heated, the CNTs, through thermal expansion, may undergo a change in their respective geometry, length, orientation, etc. In some other aspects according to the present disclosure, nano-engineered surfaces may be used to improve surface aerodynamics, may be used to improve surface hydrodynamics, or may be used as nano-reflectors.

In some embodiments, and according to aspects of the present disclosure, coated or uncoated nanoparticles (e.g., CNTs, CNT forests, etc.) may be controlled or manipulated through several methods, including chemical reactions, electromagnetic fields, heat, and densification (e.g., CNT forests having various densities). These methods may occur before, during, and/or after forest growth. CNTs, including CNT forests, may be formed on a substrate with varying heights, orientation, and density.

As previously mentioned, various aspects of the present disclosure relate to employing a combination of changing the shape or orientation of nanoparticles (e.g., CNTs, CNT forests, etc.) formed on a substrate, by applying a surface coating or treatment to the nanoparticles and/or substrate, and applying an active stimulus (e.g., electrical, thermal, magnetic, etc.) to the nanoparticles and/or substrate to achieve nanoscale actuation of a material (e.g., nanoscale active reversible and reusable dry adhesion, nanoscale interlock fastening, etc.). In an exemplary embodiment, the shape or orientation of nanoparticles (e.g., CNTs, CNT forests, etc.) may transition from a first state (e.g., shape) to a second state (e.g., shape) and vice versa in the presence, or absence, of the active stimulus (e.g., electrical, thermal, magnetic, etc.) to the nanoparticles and/or substrate. In an exemplary embodiment, these nanoparticles (e.g., CNTs, CNT forests, etc.) may maintain a stable state following a shape change from a first shape to a second shape. That is, nanoparticles as taught herein may maintain their second shape if the active stimulus is removed. The stable state may correspond to a first state where the nanoparticles are configured in a first shape, and in which a field or active stimulus is absent (i.e., no field or active stimulus is applied to the nanoparticles).

In some embodiments, the nanoparticles as taught herein enter an unstable state following a shape change from a first shape to a second shape. That is, nanoparticles as taught herein may automatically return to their first shape when the active stimulus is removed.

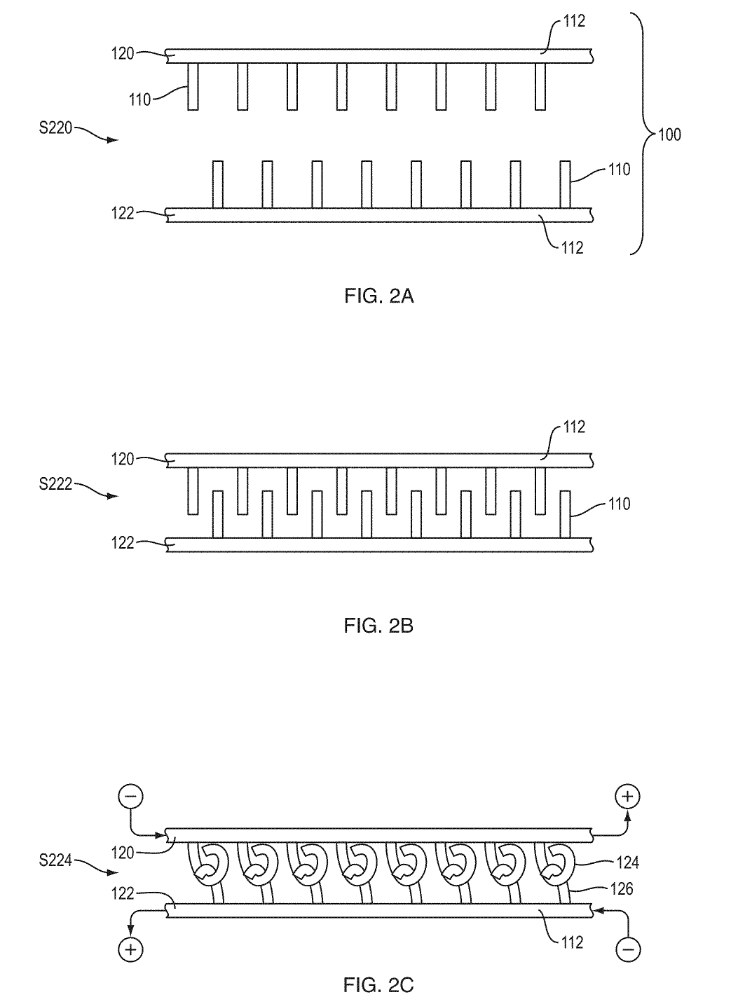

According to various aspects of the present disclosure, the nanoparticles (e.g., CNTs, CNT forests) may be coated or surface treated with a suitable material to permit the nanoparticles to change shape in response to the aforementioned active stimulus. In other examples, carbon nanotube/shape-memory polymer composites may be formed on a substrate, in which the CNT/SMP nanocomposite may achieve a sufficient shape memory effect in response to an active stimulus (e.g., electrical, thermal, magnetic, etc.). In an exemplary embodiment, and according to aspects of the present disclosure, CNTs may be formed throughout a shape-memory polymer matrix to form a CNT/SMP nanocomposite. In such an example, the CNT/SMP nanocomposite may be grown, attached, or formed on a suitable substrate. The detailed description with respect to FIGS. 2A-2C, 3A-3C, and 4A-4C may further illustrate exemplary applications of CNT shape memory in which the presence, or absence, of an active stimulus (e.g., electrical, thermal, magnetic, mechanical, etc.) may cause the nanoparticles (e.g., CNTs, CNT forests) to change shape.

Shape-memory polymers (SMPs) may be used to change the shape of CNTs (e.g., CNT pillars, CNT forests, etc.) according to aspects of the present disclosure. The use of electricity to activate the shape-memory effect of polymers may be desirable for applications where it would not be possible to use heat. In some embodiments, SMP composites with CNTs, short carbon fibers (SCFs), carbon black, or metallic Ni powder may be utilized by the dry adhesion systems described herein. These conducting SMPs may be produced by chemically surface-modifying multi-walled carbon nanotubes (MWNTs) in a mixed solvent of nitric and sulfuric acid, with the purpose of improving the interfacial bonding between the polymers and the conductive fillers. The shape-memory effect in these types of SMPs have been shown to be dependent on the filler content and the degree of surface modification of the MWNTs, with the surface modified versions exhibiting good energy conversion efficiency and improved mechanical properties.

According to various embodiments of the present disclosure, and as previously mentioned, a coating or surface treatment may be applied to the nanoparticles (e.g., CNTs, CNT forests) as taught herein. It can be appreciated that the coating or surface treatment may also be applied to one or more surfaces of an associated substrate (e.g., adhesive material) on which the nanoparticles are formed. In an exemplary embodiment, these coated nanoparticles may be actively controlled to change from a first shape to a second shape in response to the aforementioned active stimulus or energy field. When the active stimulus is applied, reversible and reusable dry adhesive materials as taught herein, having associated coated nanoparticles formed on the materials thereon, may be selectively controlled to entangle and/or untangle. That is, the coated nanoparticles, in response to the active stimulus, may form an active nanoscale bond. In some exemplary embodiments, removal of the active stimulus may cause reversible and dry adhesive materials as taught herein to untangle and separate from each other. Dry adhesive materials may be releasable in response to the active stimulus such that no damage may occur to the nanoparticles used for interlocking or to the associated substrate on which the nanoparticles are formed (e.g., adhesive material).

In an exemplary embodiment, the nanoparticles as taught herein may be coated or surface treated with nanomagnetic particles. In doing so, the nanomagnetic particles may be controlled with the active stimulus or energy field as previously mentioned. In an exemplary coating process, a first layer of nanomagnetic particles may be applied to the nanoparticles (e.g., CNTs, CNT forests, etc.) formed on a substrate as taught herein. The layer of nanomagnetic particles may then be coated with a second layer comprising a shape memory alloy. In an exemplary embodiment, the nanomagnetic particles may be configured to guide the coated nanoparticles (e.g., CNTs, CNT forests, etc.) into a first shape (e.g., first geometry, first orientation, first configuration, etc.). Once a specific first shape is selected, the assembly may be heat treated using a first temperature setting in order to use the shape memory alloy to remember the specific first shape. Subsequently, an active stimulus (e.g., magnetic field) may be employed to guide the coated nanoparticles (e.g., CNTs, CNT forests, etc.) into a second shape (e.g., second geometry, second orientation, second configuration, etc.). The second shape may be different than the first shape. A second temperature setting, which may be a different temperature than the first temperature setting, may be used to heat treat the assembly in order to use the shape memory alloy to remember the specific second shape. Once the aforementioned steps are executed, the coated nanoparticles as taught herein may retain the ability of transforming from shape to shape (e.g., a first shape to a second shape, and vice versa) in response to an active stimulus (e.g., change in temperature). In some embodiments, and as taught throughout the present disclosure, the change in temperature may be applied to the assembly externally or may use a heating element as taught herein to heat up the carbon nanotubes by virtue of their resistance. In response to a temperature change, the shape memory alloy layer may permit a user to control or reconfigure the coated nanoparticles (e.g., CNTs, CNT forests, etc.) to change from a first shape to a second shape, and vice versa.

In alternative embodiments, a shape memory polymer may be used instead of a shape memory alloy. For example, a liquid crystal elastomer may be used instead of the aforementioned nanomagnetic particles. In embodiments where a liquid crystal elastomer are used, the coated nanoparticles may change their shape proportionally in response to an application of heat. In such an example, a layer of liquid crystal elastomer may be coated over the nanoparticles as taught herein. Heat, applied either externally, via the internal heating element, or by electrical conductivity, may be employed to excite the liquid crystal polymer into various shapes (e.g., geometries, orientations, configurations, etc.). In such an example, the shape of the coated nanoparticles may change as a function of the temperature (i.e., the amount of heat applied). The liquid crystal elastomer may change from an open configuration to a closed configuration, and vice versa, based on the temperature (i.e., the amount of heat applied).

In alternative embodiments, the nanomagnetic particles described herein may be controlled via a magnetic field. That is, the nanomagnetic particles, coated over the carbon nanotubes, may be driven magnetically. In some embodiments, a shape memory polymer may be formed with magnetic particles disposed within the polymer. In response to a magnetic field, the magnetic attraction of the nanomagnetic particles may cause the coated carbon nanotubes to change shape. In some embodiments, magnetic attraction may change the coated nanoparticle (e.g., coated CNTs, coated CNT forests, etc.) from a first shape (e.g., pillars) into a second shape (e.g., hooks, loops, etc.) Alternatively, the coated nanoparticles may be shaped as hooks or curves in an initial state (e.g., first shape), and may change to a second state (e.g., second shape) in response to a magnetic field. The magnetic field may cause the coated nanoparticles, which may be shaped as hooks and/or loops, to stand up as pillars thereby releasing or disengaging the nanoparticles taught herein. When the nanoparticles disengage, the reversible and reusable dry adhesion interlocking fastener, as taught herein, may be released or separated.

In some embodiments, CNT properties, such as, for example, conductivity or stiffness, may also be controlled by surface treatments or coatings following the growth of the nanoparticles (e.g., surface treated CNTs or surface treated CNT forests). Coating or surface treatments may be used to anchor the nanoparticles for use as robust surface contacts. In some embodiments, slip may be controlled by plasma etching the top surface of the CNT forests before capillary forming.

In an exemplary embodiment, a surface coating or treatment to improve or enhance electrical conductivity may comprise one or more of the following: copper, silver particles, conductive organic polymers, carbon black, or any other suitable metallic particles. Additional coatings comprising multiple metals or combinations of metals, semiconductors, insulators (e.g., oxides), and/or conductive soft materials may be used. In some embodiments, and according to aspects of the present disclosure, a surface coating or treatment may be applied to reduce the electrical conductivity of the CNTs as taught herein. In doing so, the CNTs may heat up faster in response to an electrical current.

Nanoparticles (e.g., CNTs or CNT forests) fabricated having unidirectional and/or multidirectional curvature may require additional stiffness and/or improved mechanical properties to maintain durable surface contacts to achieve robust dry adhesion between nanoparticle surfaces. Surface treatment of CNTs may be necessary to improve mechanical resilience of the nanostructures in response to repeated loading (e.g., numerous iterations of reversible and reusable dry adhesion). In an exemplary embodiment, a surface coating or treatment to improve or enhance mechanical properties (e.g., stiffness) may comprise thin layers of metals with low melting temperatures (e.g., gold, silver, titanium, titanium oxide). In some embodiments, polymers or polymer fiber fillers may also be applied as a surface treatment to improve the mechanical resilience of the nanostructures as taught herein.

In an exemplary embodiment, and according to aspects of the present disclosure, any suitable surface treatment process (e.g., wet and/or dry post-processing steps) may be used to surface treat the nanoparticles to further tune their properties and functionality. For example, low-density bent CNT pillars may be transformed into robust, densely packed CNT structures by capillary forming. In such a scenario, the substrate may be exposed to a stream of heated acetone vapor, which may cause the acetone to condense on the CNTs and substrate, and infiltrate each CNT microstructure. Once the acetone has evaporated, the CNT forest may shrink laterally due to the surface tension of the shrinking meniscus. In other exemplary embodiments, capillary forming of vertical CNT microstructures may increase the Young's modulus during compression (e.g., around a 100-fold increase from about 50 MPa to 4 GPa). Lastly, surface treatments or coatings may be used to preserve the curved geometries, shapes, and/or orientations of the individual CNTs, portions of the CNT forest, or the entire CNT forest by increasing the lateral deflection of the CNT pillar structures. Alternatively, curved CNT microstructures, or any other suitable nanoparticle described herein, may be coated conformally via vapor phase methods, thereby enabling decoupled control of geometry and mechanical properties.

By controlling the orientation and/or shape of both individual carbon nanotubes or portions of CNT forests, a user may control the overall nano-engineered surface at a macro level (e.g., interlock fastening of two dry adhesion materials). As previously mentioned, nanoparticles (e.g., CNTs, CNT forests, etc.) may be coated with a coating or surface treatment to permit the carbon nanotubes to be controlled in response to an active stimulus as taught herein. In an exemplary embodiment, CNT forests may function as dry adhesives and that a specific pattern of a CNT forest may enable control of the interface compliance while maintaining large numbers of micro- and nanoscale contacts. For example, and according to aspects of the present disclosure, by controlling individual CNTs or portions of CNT forests formed on a surface of a material, a user may selectively interlock or fasten individual CNTs (or a portion of a CNT forest) from a surface of a first material to individual CNTs (or portions of a CNT forest) from a surface of a second material. However, at a later time, it may be desirable for the user to release the first material from the second material. Therefore, according to aspects of the present disclosure, methods and materials are also described herein to permit the dry adhesion function described above to be reversible (i.e., unlocking or releasing the CNT-to-CNT joint).

As such, and according to aspects of the present disclosure, various sources may be used to achieve a locking and/or release of the first material with the second material. Examples of such sources may include a magnetic field, an electrical field, the application of a temperature (e.g., via a heating element disposed within a substrate), the application of a mechanical load or pressure, or any other suitable energy source capable of controlling nanoparticles formed on or affixed to a surface of a material (e.g., control individual CNTs or portion of CNT forests).

It should be appreciated that as taught herein, the first and second materials may achieve an interlocking or fastening on a nanoscale. This nanoscale connection may not be visible to the naked eye of a user.

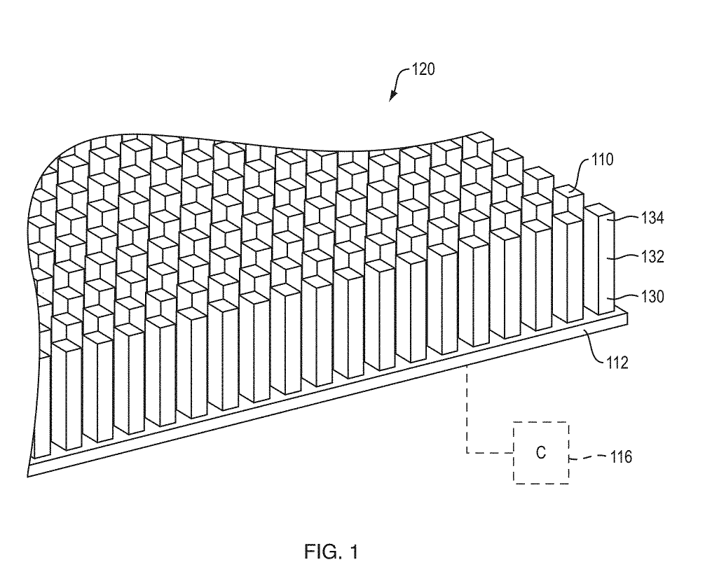

With initial reference to FIGS. 1 and 2A, an exemplary actively reversible and reusable nanoscale dry adhesion system 100 is illustrated comprising a first dry adhesive material 120 and a second dry adhesive material 122. The dry adhesive material 122, which may be referred to as the opposite or complimentary material to the dry adhesive material 120 throughout the present disclosure, may include similar features to the dry adhesive material 120.

In an exemplary embodiment, the dry adhesion system 100 may be used for a variety of industrial interlock fastening applications, such as, e.g., in the construction of vehicles, buildings, furniture, consumer electronics, aviation, clothing, or any other suitable fastening applications where a robust interlocking fastener technology may be required. In some embodiments, the dry adhesion system 100 may be reversible and reusable, that is, interlockable and releasable to allow fastening and separation without damage to two or more objects (e.g., articles, composite parts, etc.). Similar to macro-scale surfaces utilizing macro-scale interlocking fasteners, such as VELCRO® fasteners, nanoscale surfaces including CNT hooks, CNT loops, CNT, rivet heads, CNT mushrooms, CNT spheres, CNT posts, or other suitable nanoparticles may be used to cause two opposed nano-engineered surfaces to grip each other to achieve dry adhesion. In such an example, CNT hooks, CNT loops, CNT rivet heads, CNT mushrooms, CNT spheres, CNT posts, or other suitable nanoparticles may be formed on any suitable substrate and manufactured using processes described throughout the present disclosure. In some aspects of the present disclosure, the nanoscale dry adhesion system 100 may be interlocked or fastened using a mechanical load, such as, for example, a user pressing the first dry adhesive material 120 together with the second dry adhesive material 122 such that the materials 120 and 122 interlock. In this example, it can be appreciated that the carbon nanotubes formed on the dry adhesive materials 120 and 122 induce a strong attractive force that may operate on the atomic scale. These atomic scale forces are known as the van der Waals force, and may induce first and second dry adhesive materials to join each other by virtue of a nanoscale bond using a high degree of force between the carbon nanotubes.

In other aspects of the present disclosure, the dry adhesion system 100 may be interlocked or fastened together with a first application of an active stimulus, such as, for example, an electric, thermal, or magnetic field. In such an example, the application of the active stimulus may cause the nanoparticles (e.g., individual CNTs, CNT forests, etc.) to change their shape and/or orientation such that the nanoparticles of the first dry adhesive material 120 entangle, interlock, or dry adhere to the nanoparticles of the second dry adhesive material 122. A second application of the active stimulus may also be used to release or unlock the nanoparticles of first dry adhesive material 120 from the nanoparticles of the second dry adhesive material 122 (e.g., release CNTs of the first material 120 from CNTs of the second material 122). It can be appreciated that more than two dry adhesive materials may be used with the dry adhesion system 100. In some embodiments, the active stimulus may be applied selectively, for example, when unlocking or locking the fastening systems described herein. In some embodiments, the active stimulus may be applied continuously.

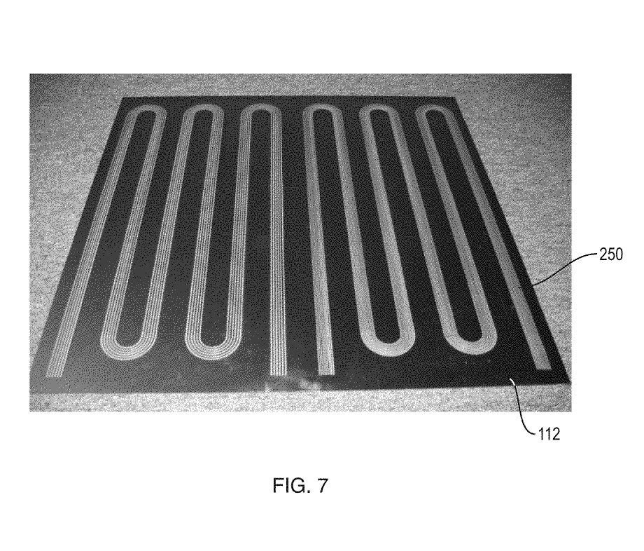

Continuing with reference to FIG. 1, illustrated is a section of the dry adhesive material 120 adapted for use as a fastener in an article (not shown). The first dry adhesive material 120 may comprise a substrate 112, and a plurality of CNT pillars 110 rising from the substrate 112 (e.g., grown via any suitable CNT manufacturing process). One or more electrodes may be embedded within the substrate 112 and/or formed on one or more surfaces of the substrate 112 (e.g., an exemplary electrode 250 depicted in FIG. 7 and described hereto within). The substrate 112 of the dry adhesion system 100 may comprise either a single layer or have multiple layers. The substrate 112 may comprise various materials, for example, materials conducive for the growth of CNTs and CNT forests. In some embodiments, the substrate 112 may be comprised of a film, and may contain apertures, slits, grooves, or embossed features to enhance mechanical properties of the substrate 112. In an exemplary embodiment, the substrate 112 may be coated on one or both sides to improve conductivity and/or stiffness throughout the substrate 112. The substrate 112 may also be formed from an elastic or non-rigid material (e.g., carbon fabric). In an exemplary embodiment, the substrate 112 may contain regions of elasticity so that the dry adhesion system 100 may conform to a surface of an article (e.g., composite parts to be joined together to form a final part).

As depicted in FIG. 1, the dry adhesive materials 120 and 122 of the dry adhesion system 100 may be in electrical communication via wired and/or wireless means to a controller 116. In some embodiments, controller 116 may comprise a button or switch connected to a battery or suitable power source. In some embodiments, a separate controller for each dry adhesive material 120 and 122 may be included in the dry adhesion system 100. In an exemplary embodiment, the controller 116 may comprise a button, a switch, or any other suitable device for applying an active stimulus or field throughout the system 100 (e.g., a button to permit an electrical field or thermal gradient to be applied to one or more dry adhesive materials 120 and 122 so that nanoscale interlocking adhesion may be achieved). In some embodiments, the controller 116 may further include additional features, e.g., a processing device, a transmitter, a receiver, a graphical user interface (GUI), combinations thereof, or the like, and can be configured to receive input from a user to control the dry adhesion system 100 according to aspects of the present disclosure provided herein.

In some embodiments, and as taught herein, the controller 116 may be configured to apply an active stimulus or field to the first adhesive material 120, and not the second adhesive material 122. In some embodiments, the controller 116 may be configured to apply an active stimulus or energy field to the second adhesive material 122, and not the first adhesive material 120. In some embodiments, and as previously mentioned, separates controllers may be operatively connected to each of the first and second adhesive materials 120 and 122 such that each adhesive material responds to a different field or active stimulus from the other. Accordingly, each separate controller may independently actively change the respective shapes of the coated nanoparticles formed on the first and second adhesive materials 120 and 122. In an exemplary embodiment, where two reversible and reusable dry adhesion materials are bonded together, an active stimulus may be applied to either one or both the dry adhesion materials to change the shape of the coated nanoparticles thereon in order to release the two dry adhesion materials from each other (e.g., untangle and peel apart two nanoscale dry adhesion materials).

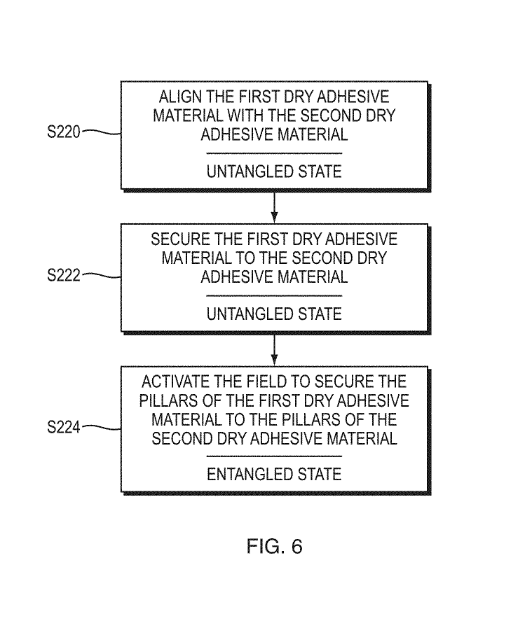

Continuing with reference to FIG. 1, the CNT pillars 110 may be formed in a variety of shapes having varying cross-dimensional patterns and/or dimensions. The CNT pillars 110, as depicted in FIG. 1, are rectangular in shape, however, may be formed to achieve any shape permitted by state-of-the-art CNT manufacturing. In some embodiments, the CNT pillars 110, and during the fabrication of CNTs or CNT forests, may be formed on a substrate in a variety of shapes and configurations, such as, e.g., curved, folded, square-shaped, rectangular-shaped, ellipsoidal, circular, conical, disc-shaped, pillars, tubes, notches, rivets, ribs, hooks, loops, arches, semi-circles, posts, spheres, composite volcanos, shield volcanoes, domes, cones, cinder cones, etc. FIGS. 6-13B, which will be described in further detail hereto within, depict exemplary shapes and configurations of the CNT pillars 110.

The CNT pillars 110 may be grown as single wall carbon nanotubes, multi-wall carbon nanotubes, or a combination of both throughout the substrate 112. In some embodiments, and according to aspects of the present disclosure, the CNT pillars 110 of the dry adhesion system 100 may be formed as nanoparticles that are not formed from carbon nanotubes. As previously mentioned, and representative of many CNT structures depicted throughout the figures, the CNT pillars 110 may not be visible to the naked eye of a user owing to their nanoscale size; thus, the user when using the dry adhesion system 100 may not receive tactile feedback from the CNT pillars 110 (e.g., a user may not feel the nanostructures with the user's fingers). In other words, CNT microstructures and CNT forests grown on the substrate 112 may not be felt by a user, in contrast to the user's ability to feel, for example, macroscale VELCRO® hook and loops fasteners.

Returning to FIG. 1, each CNT pillar 110 may include a height H and a cross-sectional area A. For example, the CNT Pillar 110 may include a width W and a length L from which the cross-sectional area A may be calculated. In some embodiments where the CNT pillar 110 may be cylindrical in shape, the pillar may include a diameter D (or range of diameters throughout a given CNT pillar 110). The CNT pillars 110 may further comprise a base section 130, a midsection 132, and a top section 134. In an embodiment, the CNT pillars 110 may be spaced apart in a pattern. For example, in some embodiments, patterns of the CNT pillars 110, or CNT forests, may be randomly distributed, dispersed in a pre-determined pattern, dispersed in a pattern such as a staggered array, or dispersed as multiple discrete clusters of CNTs, etc. Patterns may result in the CNT pillars 110 being disposed on the substrate 112 in a directional orthogonal to the substrate, or slanted in a first direction. In some embodiments, portions of a CNT forest may comprise the CNT pillars 110 being orthogonal relative to the substrate 112 in some areas, while disposed at an angle relative to the substrate 112 in other areas.

In an exemplary embodiment, the plurality of CNT pillars 110 may be referred to as a CNT forest. In an exemplary embodiment, the CNT pillars 110 may achieve a select geometry or orientation to temporarily change the configuration of the CNT forest by applying an electric field, heat, magnetic, or a combination thereof. In this example, the CNT pillar 110 or the CNT forest may temporarily change like a shape memory alloy, or a shape memory polymer, such that the shape of the CNT pillar 110 may mimic a specific shape or orientation (e.g., a hook, loop, rib, sphere, post, pillar, folded shape, rivet, curved surface, mushroom-shaped hook, etc.). In some aspects of the present disclosure, the CNT pillar 110 may change shape and/or orientation to emulate the setae found on the toes of a Gecko. It can be appreciated that the CNT pillars 110, including the top section 134, may be formed to provide enhanced conforming and contact area between the CNT pillars 110 of the first dry adhesive material 120 and the CNT pillars 110 of the complimentary second dry adhesive material 122.

In some embodiments, the first dry adhesive material 120 and/or the second dry adhesive material 122 may comprise a protecting material to prevent adhesion until desired. In some embodiments, an intermediary layer (not shown) may be attached or secured to a bottom surface of the substrate 112 (e.g., the surface without the CNT pillars 110) such that the intermediary layer can be bonded, welded, or otherwise secured to a composite part. The composite part may comprise an airplane part, automobile part, furniture part, consumer electronic, or an article of clothing. In other embodiments, the substrate 112 may be formed integrally with the composite part such that the CNT pillars 110 are integral to the composite part in order to permit two or more composite parts to be joined together via the nanoscale dry adhesion system 100 as described herein.

The CNT pillars 110, as illustrated in FIG. 1, may include an immense and appreciable amount of surface area, which may be achieved over a small 2D plane (e.g., the dry adhesive materials 120 and 122). In an exemplary embodiment, the dry adhesion system 100 may provide a substantial amount of surface contact area such that an enormous amount of latching force may be generated between the CNT pillars of each respective dry adhesive material. On a nanoscale level, the interlocking fastener peel and shear strength between the dry adhesive materials 120 and 122 meets or exceeds that of traditional joining methods, such as, for example, bonding or welding. In an exemplary embodiment, and according to aspects of the present disclosure, the interlocking fastener peel and shear strength may exceed traditional joining methods owing to the additional contact surface area of the nanoengineered surfaces having smaller fastening elements. In some embodiments, and according to aspects of the present disclosure, a strip or portion of the dry adhesive materials 120 and 120 may be deposited, bounded, mounted, or otherwise attached to a surface of a pre-fabricated metallic or composite part. In such an example, the two or more parts may be pressed or mechanically joined together post-fabrication to create a more complex or built-up part without heat, vibration, and/or chemicals. For example, a nano-engineered surface comprising the dry adhesive material described herein may be used to mount or attach a first metallic automobile part to a second automobile part. In other exemplary embodiments, a rib may be mechanically press fitted between a pair of two respective skins to create an I-beam like part. In other embodiments, two skins may be mechanically press fitted together to form a thicker skin.

As described herein, and according to aspects of the present disclosure, the dry adhesion system 100 may be adapted for use in a variety of industrial applications. For example, when adapted for use in an aircraft, thousands of pounds of metallic rivets may be avoided. Owing to the lighter weight of the CNTs, aircraft components may be joined together using the dry adhesion system 100 as described herein to save on overall aircraft weight, which may save on manufacturing, maintenance, and fuel costs. Large, complex component parts may be assembled quickly using the nanoscale dry adhesion system 100, which may lower production and manufacturing costs, and require little tooling. As the nanoparticles and nano-engineered surfaces described herein would be on a micron-scale, at the largest, no rough/course surface texture may be felt by a user on either side of the dry adhesion system 100. For example, and as referenced to earlier, nanostructures described herein would be naked to the visible eye, and on a scale small enough where texture of the dry adhesion system 100 would be virtually unrecognizable. Beyond structural applications, the dry adhesion system 100 may be incorporated into the design of textiles and/or clothing to achieve reversible and reusable adhesion or for semi-permanent textile joining. In some embodiments, the joint created by the nanoscale interlocking fastener of the dry adhesion system 100 could be significantly stronger than traditional VELCRO® fasteners. However, the joint may not be as conducive to simply pull apart the hook-and-loop fasteners as in traditional macro-scale VELCRO® fasteners.

Methods of operating the dry adhesion system 100 are described herein. In an exemplary embodiment, the dry adhesion system 100 may permit the dry adhesion process, described above, to be reversible so that the dry adhesion system 100 may be reversible and reusable. In other words, a user may seek to adhere the first dry adhesive material 120 to the second dry adhesive material 122, subsequently unlock or release the first dry adhesive material 120 from the second dry adhesive material 122 so that the dry adhesion system 100 is reversible. In exemplary embodiments, and according to aspects of the present disclosure, the first dry adhesive material 120 and the second dry adhesive material 122 may be entangled and untangled multiple times such that the dry adhesive system 100 may achieve reusability.

With reference now to FIGS. 2A-2C and 6, an exemplary method of using the dry adhesion system 100 is described. FIG. 2A depicts the first dry adhesive material 120 comprising the CNT pillars 110 extending from a surface of the substrate 112. The second dry adhesive material 122 similarly comprises the CNT pillars 110 extending from a surface of the substrate 112. At a step 220, and as depicted, the first and second dry adhesive materials 120 and 122 may be aligned and brought towards each other, however, are not in physical contact yet and are in an untangled state. That is, the CNT pillars 110 of the respective first and second dry adhesive materials 120 and 122 are not in contact.

At a step 222, as best shown in FIG. 2B, the first dry adhesive material 120 may be brought together and secured to the second dry adhesive material 122, as depicted, such that the two dry adhesive materials may be in physical contact. That is, the CNT pillars 110 of the respective adhesive surfaces first and second dry adhesive materials 120 and 122 may be in physical contact; however, dry adhesion may not be achieved yet. The CNT pillars 110 remain in an untangled state.

At a step 224, as best shown in FIG. 2C, and according to aspects described in the present disclosure, the first and second dry adhesive materials 120 and 122 may join or bond together by applying a field or active stimulus as taught herein (e.g., thermal, electric, magnetic, etc.) to either the first dry adhesive material 120 or 122, or both. As a result, the CNT pillars 110 of the respective first and second dry adhesive materials 120 and 122 may entangle, as depicted in FIG. 2C. In an exemplary embodiment, the active stimulus or field may be applied via the controller 116 (e.g., pressing a button, pressing a switch, or actuating any other suitable device to deliver a thermal (heat), electric, and/or magnetic field). By applying a magnetic field, the application of heat, the application of an electrical current, or a combination of one or more of these fields, carbon nanotubes disposed on the first dry adhesive material 120 may entangle or otherwise be joined to carbon nanotubes on the second dry adhesive material 122 as taught herein.

In some embodiments, and as previously mentioned, the first and second dry adhesive materials 120 and 122 may be operatively connected to two respectively separate controllers. In such an example, the first adhesive material 120 may respond to a first field or active stimulus when a first controller is activated, and the second adhesive material 122 may respond to a second field or active stimulus when a second controller is activated.

In some embodiments, separate fields or active stimuli may be applied to the first and second dry adhesive materials 120 and 122; however, no activation of the active stimulus may occur until the first and second dry adhesive materials 120 and 122 are brought in contact with each other. That is, each of the first and second dry adhesive materials 120 and 122 may respond to a separate electrical current, and may not form a complete electrical circuit until the two conductive first and second dry adhesive materials 120 and 122 are brought into physical contact. In such a scenario where no physical contact is made, activation of the field or active stimulus may not occur. In such an example, the coated nanoparticles as taught herein may not change shape in order to achieve actively reversible and reusable dry adhesion until the two adhesive materials form a closed electrical circuit. It can be appreciated that various other electrical configurations may be used.

In some embodiments, and according to aspects of the present disclosure, a heating system, comprising a heating element, may be disposed within or adjacent to the substrate 112 to deliver heat for the field as taught herein. In some embodiments, electrical wires and/or electrodes may be disposed within the substrate 112 to deliver an electric field. For example, wiring or electrodes may be disposed throughout the substrate 112, as best shown in FIG. 7, to deliver an electric current. One or more suitable sources for delivering electromagnetism or magnetism for the field may also be employed. The one or more electromagnetic or magnetic sources may be formed integral with the substrate 112 or may be attached or operably connected to the dry adhesion system 100. Heating sources, electrical sources, and/or magnetism sources may be operatively connected to both the first and second adhesive materials 120 and 122 in some embodiments. In some other embodiments, heating sources, electrical sources, and/or magnetism sources may be operatively connect to one of the dry adhesion materials, but not the other.

As referenced to earlier, this aforementioned field may temporarily deform the CNT pillars 110 into the CNT loops 124 and the CNT hooks 126, as shown, similar to how a shape memory alloy may change shape. The CNT pillars 110 of the first dry adhesive material 120 may change shape from a pillar to a loop. Similarly, the CNT pillars 110 of the second dry adhesive material 122 may change shape from a pillar to a hook. In doing so, the dry adhesive system 100 may achieve hook-and-loop dry adhesion on a nanoscale. Hook-and-loop nanoscale fastening allows for significantly more surface or contact area than in a macroscale VELCRO® hook-and-loop fastener. Owing to the increased surface and contact area as a result of CNTs, a higher degree of force may be achieved; thus, permitting a more robust joint or bond between dry adhesive materials. This nanoscale adhesion may cause the first and second dry adhesive materials 120 and 122 to adhere together with a tremendous degree of force.

The flow of electrons depicted in FIG. 2C are exemplary, and the dry adhesion system 100 may utilize any suitable electric field source, and may permit the flow of electrons (e.g., using the one or more electrodes or one or more sources of electrical current as taught herein) in either direction to achieve the foregoing dry adhesion. Moreover, in some embodiments, the flow of electrons may occur through the first adhesive material 120, and not the second adhesive material 122. In some embodiments, the flow of electrons may occur through the second adhesive material 122, and not the first adhesive material 120. In some embodiments, the flow of electrons may occur through both the first and the second adhesive materials 120 and 122. Moreover, it should be appreciated that any suitable source of electromagnetism or heat that may change the shape of the CNT pillars 110 as described above may be used by the dry adhesion system 100. In some embodiments, the application of the active stimulus or field may be periodic or continuous. For example, an electric current may be applied to the CNT pillars 110 continuously so that they retain their new shape under and in response to the electric current. When the electric current is removed, the CNT pillars 110 may return to their original shape and/or orientation; thus, causing the CNT pillars 110 from the respective first and second dry adhesive materials 120 and 122 to untangle, which would release the first dry adhesive material 120 from the second dry adhesive material 122.

In a step 226 (not shown), and according to some embodiments, a user may also release or untangle the first dry adhesive material 120 from the second dry adhesive material 122 by, once again, applying the same active stimulus or field applied during step 224. In doing so, the dry adhesion system 100 may be reversible. The dry adhesion system 100 may then be reused as many times as necessary.

In some embodiments of the present disclosure, a chemical or solvent may be used to further densify, deform, and/or re-align the carbon nanotubes formed on the substrate 112. In other words, a chemical or solvent may be used to further densify, deform, and/or re-align the CNT pillars 110 such that the first and second dry adhesive materials 120 and 122 may be separated or released from each other. However, with this approach, the chemical or solvent may permanently change or disfigure the shape, geometry, and/or configuration of the CNT pillars 110 formed on the substrate 112 such that the dry adhesion system 100 may not be re-usable. In doing so, a reversible fastening system may be facilitated, but may permit for single use adhesion.

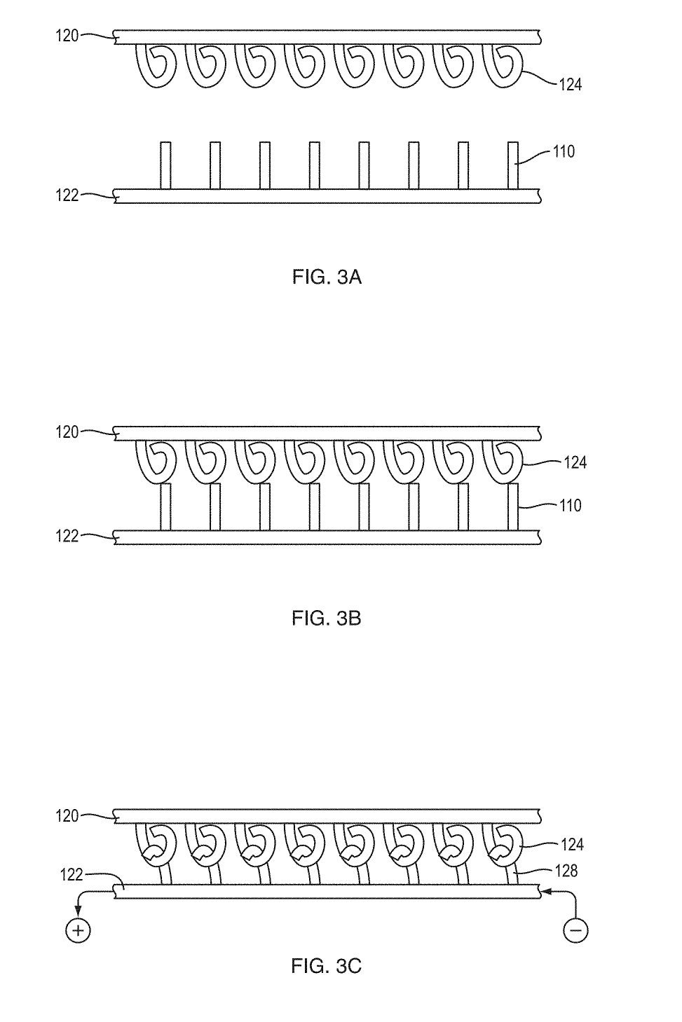

Turning to FIGS. 3A-3C, a second dry adhesion system 100 is described. In this embodiment, the CNT pillars 124 may be grown, according to aspects of the present disclosure, on the substrate 112 of the first dry adhesive material 120. The CNT pillars 124 may take form as a loop in shape, orientation, and/or geometry. The CNT pillars 110, as previously referenced to, may be grown on the substrate 112 of the second dry adhesive material 122. The CNT pillars 110 may be trained like a shape memory alloy to transition from pillars to hooks.

When brought together, as described by the methods recited with respect to FIGS. 2A-2C, and as shown in FIG. 3B, the first and second dry adhesive materials 120 and 122 do not adhere to each other, and may remain in an untangled state. At this point, the first and second dry adhesive materials 120 and 122 may slide off each other when brought together because no dry adhesion is achieved. However, similar to the method described above, when an active stimulus or field (e.g., thermal, electric, magnetic, etc.) is applied to the second dry adhesive material 122 via the controller 116 (e.g., pressing a button, pressing a switch, or actuating any other suitable device to deliver a thermal (heat), electric, and/or magnetic field), the CNT pillars 110 may change shape from the CNT pillars 110, as shown in FIG. 3B, to the CNT hooks 128, as shown in FIG. 3C. As depicted in FIG. 3C, application of an electric current to the second dry adhesive material 122, the CNT pillars 110 deforms or changes the shape of the CNT pillars 110 into the CNT hooks 128 to entangle or join together with the CNT loops 124 of the first dry adhesive material 120. In this example, an active stimulus or field (e.g., heat, electrical current, magnetism, etc.) may be applied to a single adhesive material to achieve nanoscale dry adhesion.

According to aspects of the present disclosure, the CNT pillars 110 may maintain a stable state following a shape change from pillars to hooks, or pillars to loops, or some other transformation from pillars to another shape as taught herein. During the stable state, the CNT pillars 110 may maintain their second shape if the active stimulus is removed. The stable state may correspond to a first state where the nanoparticles are configured in a first shape, and in which an active stimulus or field is absent (i.e., no field is applied to the nanoparticles).

According to aspects of the present disclosure, the CNT pillars 110 may enter an unstable state following a shape change from a first shape to a second shape. That is, the nanoparticles as taught herein automatically return to their first shape if the active stimulus is removed.

As with the other embodiments described herein, the controller 116 may be pressed or actuated again to remove the active stimulus or field in order to separate the first and second dry adhesive materials 120 and 122 so that the dry adhesion system 100 may be reversible and/or reusable. It can be appreciated that a number of combinations of shapes, geometries, and/or configurations of carbon nanotubes formed on the substrates 112 of the first and second dry adhesive materials 120 and 122 may occur to achieve nanoscale interlocking fastening, according to aspects of the present disclosure.

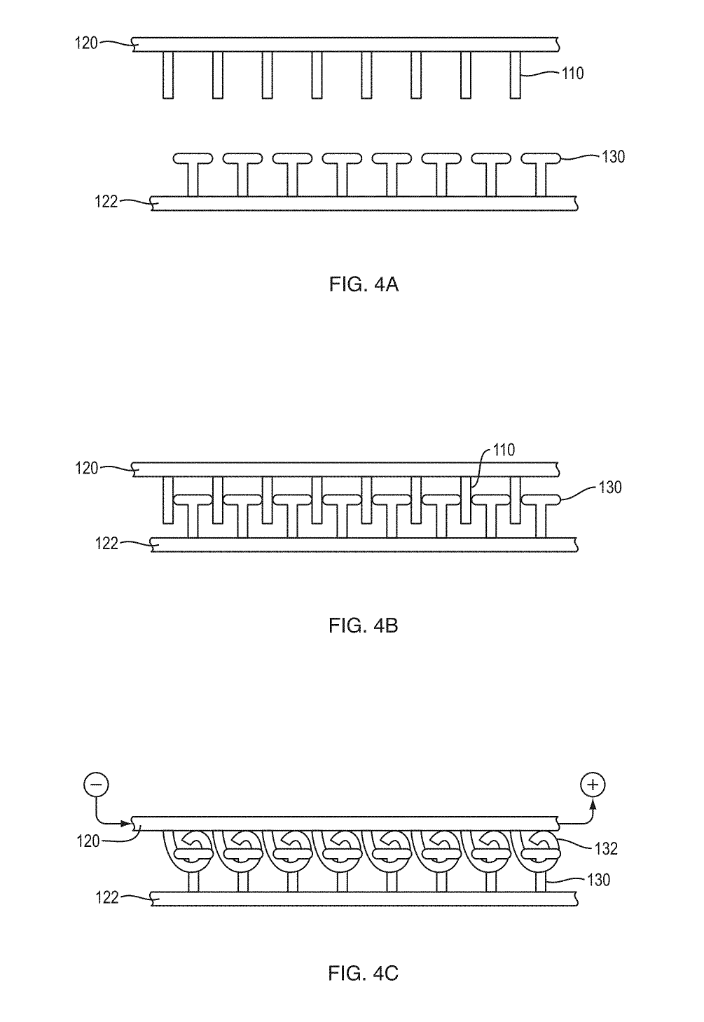

Turning to FIGS. 4A-4C, similar methods as described with respect to FIGS. 2A-2C may be employed by the dry adhesion system 100 to achieve nanoscale interlock fastening. In this example, CNT mushroom-shaped hooks 130 may be grown on the second dry adhesive material 122, as depicted in FIGS. 4A-4C, according to aspects of the present disclosure. In response to an active stimulus or field, applied via the controller 116, and as described above, the CNT pillars 110 of the first dry adhesive material 120 in FIG. 4B may change shape to form the CNT loops 132, as depicted in FIG. 4C. In doing so, the CNT hooks 130 may entangle or join together with the CNT loops 132 to achieve nanoscale dry adhesion. In this example, a single dry adhesive material (e.g., the first dry adhesive material 120) may be applied with the active stimulus or field, as taught herein. When the active stimulus or field is removed via the controller 116, the CNT loops 132 may return to their original shape as the CNT pillars 110, as depicted in FIGS. 4A and 4B. In doing so, the CNT pillars 110 may untangle from the CNT hooks 130. In doing so, the first dry adhesive material 120 may be separated from the second dry adhesive material 122.

It can further be appreciated that these various CNT shapes and CNT forests may be used by the dry adhesion system 100 to achieve a number of surface contacts (e.g., different shapes, sizes, and geometries of the CNT pillar 110) to further achieve various patterns useful in various combinations and/or configurations of nanoscale interlock fastening between the first and second dry adhesive materials 120 and 122. For example, the CNT micropillar may comprise a curved carbon nanotube microstructure. For any CNT microstructure to CNT microstructure entanglement described herein, it should be appreciated that a user may twist, insert, push, or otherwise apply an appropriate force or mechanical load to join or adhere the corresponding CNT microstructures together to achieve nanoscale dry adhesion.

According to aspects of the present disclosure herein, the CNT microstructures may change shape in response to an active stimulus or field (e.g., thermal, electric, magnetic, mechanical, etc.) and may encapsulate a CNT pillar described herein to achieve a nanoscale interlocking fastener. For example, the CNT microstructures may collapse in order to trap or otherwise secure an opposing and complimentary CNT microstructure that may be seated within the CNT microstructures. Alternatively, these CNT microstructures may extend outwardly as shown to achieve yet another CNT microstructure that may be used according to the dry adhesion system described herein.

The CNT pillars 110 may also be formed as a semi-cylindrical shape on the substrate 112. The CNT pillars 110 may be grown in a curved manner from the substrate 112. In some embodiments, and as taught herein, the CNT pillars 110 may change from a first shape in response to the active stimulus (e.g., electrical current, heat, etc.) as taught herein. In doing so, the CNT pillars 110 may curve outwardly from an initial upright position. The CNT pillars 110 may be used in actively reversible and reusable nanoscale dry adhesion according to aspects of the present disclosure.

A variety of complex CNT microarchitectures may be used in actively reversible and reusable nanoscale dry adhesion according to aspects of the present disclosure. For example, CNT micro-helices with deterministic handedness and pitch may be used for nanoscale dry adhesion. These CNT microstructures may comprise a plurality of alternating recesses and ribs, and include an opening. The opening may extend along a longitudinal length of the CNT microstructure. Alternatively, the CNT microstructures may include a helical pattern to form a CNT helix. The CNT helix may include a plurality of ribs extending helically along a longitudinal length of the CNT helix. The CNT microstructure or the CNT helix may be used as interlocking elements (e.g., pins, pegs, tenons, mortises, etc.) to achieve nanoscale adhesion according to aspects of the present disclosure. For example, the CNT microstructure or the CNT helix may be formed on a first dry adhesive material substrate, and may be inserted into a corresponding CNT microstructure formed on a second dry adhesive material substrate and shaped to receive the CNT microstructure or the CNT helix. In some embodiments, the CNT microstructure may change shape into the CNT helix, or vice versa, in response to the field or active stimulus as taught herein.

In some embodiments, the CNT microstructure may be formed on the substrate 112, and may comprise twisted propeller-like microstructures. This CNT microstructure may include a plurality of arms or blades that may be angled relative to the substrate 112. For example, the blades may form around a central pillar and may be angled. The blade, however, may be formed so that the blade may be perpendicular or substantially perpendicular to the substrate 112. According to aspects of the present disclosure, a CNT hook, or similar CNT microstructure, grown on a first dry adhesive material substrate may entangle with one or more blades grown on a second first dry adhesive material substrate. A field or active stimulus as taught herein (e.g., electrical current, heat, mechanical load, etc.) may be applied to one or more adhesive substrates, according to aspects of the present disclosure, so that CNT blades and/or CNT hooks twist, bend, or re-configure in order to ensure entanglement between the corresponding nano-surfaces of first and second dry adhesive materials.

In some embodiments, a semi-circle shaped CNT microstructure may be formed on the substrate 112. This CNT microstructure may comprise a semi-circular wall that defines corresponding opening. In an exemplary embodiment, the CNT microstructure opening may receive a corresponding CNT microstructure (e.g., CNT hook, CNT blade, CNT curved surface, etc.) to achieve nanoscale entanglement according to aspects of the present disclosure. The CNT microstructure may comprise a CNT semi-circle pillar, which may be formed on a base. The base may be formed on the substrate 112. The CNT microstructure may comprise a curved or rounded pillar, which may extend arcuately from the base. It should be appreciated that a number of curved pillars may be used to achieve nanoscale dry adhesion, according to aspects described in the present disclosure. Moreover, application of a field or active stimulus (e.g., electrical current, heat, mechanical load, etc.) may change the shape of any CNT microstructure surface described or depicted herein.

In some embodiments, the CNT microstructure may comprise concentric tubular CNT arrays shaped into concentric microstructures with overhanging walls having different slopes or radially-aligned sheets surrounding vertical needles. In this example, a field or active stimulus (e.g., electrical current, heat, magnetism, etc.) may be applied to collapse overhanging walls to change the shape of the inner array into a peg or needle. It can be appreciated that the available number, size, height, and wall-thickness combinations of these types of CNT arrays (e.g., hollow cylindrical, curved, propeller-like, helical-shaped, hook-and-loop, etc.) to be shaped into complex microstructures may be virtually limitless. It can be appreciated, therefore, that the combination of CNT microstructures suitable for nanoscale dry adhesion according to aspects of the present disclosure may also be virtually limitless.

As previously referenced, any suitable heating system may be employed by the actively reversible and reusable dry adhesion system 100, and according to aspects of the present disclosure. In some embodiments, heat may be applied to the dry adhesion system 100, including the CNT pillars 110, from the substrate 112 surface itself heating up, from a heating system attached to the substrate 112 surface, and/or a current traveling through the nanoparticles (e.g., CNTs, CNT forests) in order to heat the nanoparticles. The exemplary heating system may comprise the heating element with multiple individually addressable heating zones. In an exemplary embodiment, the heating system may employ various embodiments illustrated and described in U.S. Pat. No. 9,091,657 to Kessler et al., which is herein incorporated by reference. It should be appreciated that other heating system architectures may be employed to deliver heat (or an electrical current) to the substrate 112, including the CNT microstructures formed thereon (e.g., the CNT pillars 110), to change the shape of the CNT microstructures as taught herein to achieve nanoscale dry adhesion.

In an exemplary embodiment, one or more heating elements may be coupled to and in thermal contact with the substrate 112 and/or the nanoparticles formed thereon (e.g., the CNT pillars 110, CNT forests), the one or more heating elements may be configured to selectively and independently apply heat to the substrate 112 and/or the nanoparticles formed thereon (e.g., the CNT pillars 110, CNT forests), to selectively raise a temperature of the substrate 112 and/or the nanoparticles formed thereon (e.g., the CNT pillars 110, CNT forests), to at least a predetermined temperature to selectively reconfigure the shape of the nanoparticles (e.g., the CNT pillars 110, CNT forests), wherein upon changing shape the corresponding nanoparticles (e.g., the CNT pillars 110, CNT forests) of the first and second dry adhesive materials 120 and 122.

As taught herein, the actively reversible and reusable dry adhesion system 100 may comprise one or more electrodes that may be operably connected to the dry adhesion system 100. For example, the exemplary one or more electrodes 250 depicted in FIG. 7 may be operably connected (e.g., electrical wires, wirelessly, or any other suitable manner) to the dry adhesion system 100 to provide the first and/or the second adhesive materials 120 and 122 with an electric current. The one or more electrodes 250 may be formed on the substrate 112, as depicted. In some embodiments, the one or more electrodes 250 may be formed one or more surfaces of the first and/or the second adhesive materials. As previously mentioned, the one or more electrodes may also be formed integrally with the substrate 112. Electrodes may be used to deliver an electrical current to heat up the coated nanoparticles, as taught herein.

While principles of the present disclosure are described herein with reference to illustrative embodiments for particular applications, it should be understood that the disclosure is not limited thereto. Those having ordinary skill in the art and access to the teachings provided herein will recognize additional modifications, applications, embodiments, and substitution of equivalents all fall within the scope of the embodiments described herein. Accordingly, the invention is not to be considered as limited by the foregoing description.

What is claimed is:

1. A dry adhesion system, comprising:
a first plurality of nanoparticles formed on a first substrate and capable of changing from a first shape to a second shape in response to an active stimulus;
a second plurality of nanoparticles formed on a second substrate and capable of changing from a first shape to a second shape in response to the active stimulus; and
a switch operably connected to the first and second substrates and configured to selectively apply the active stimulus, wherein when the switch is activated, the first and second pluralities of nanoparticles change from their respective first shape to their respective second shape to interlock the first substrate to the second substrate, and wherein when the switch is deactivated, the first and second pluralities change from their respective second shape to their respective first shape to release the first substrate from the second substrate.

2. The dry adhesion system of claim 1, wherein the first and second pluralities of nanoparticles are formed from carbon nanotubes.

3. The dry adhesion system of claim 1, wherein the active stimulus is an electric current, temperature gradient, or magnetic field.

4. The dry adhesion system of claim 1, wherein the first plurality of nanoparticles are carbon nanotube pillars in the first shape and carbon nanotube hooks in the second shape.

5. The dry adhesion system of claim 4, wherein the second plurality of nanoparticles are carbon nanotube pillars in the first shape and carbon nanotube loops in the second shape.

6. The dry adhesion system of claim 5, wherein when the switch is activated the first and second pluralities of nanoparticles interlock to form a nanoscale hook and loop fastener.

7. The dry adhesion system of claim 6, wherein the nanoscale hook and loop fastener forms a structural joint that approaches or exceeds the peel and shear strength of an adhesive bond.

8. The dry adhesion system of claim 1, wherein the first substrate is attached to a first composite part, and wherein the second substrate is attached to a second composite part.

9. The dry adhesion system of claim 3, wherein electrical wires or electrodes are disposed within the first and second substrates to selectively apply the electrical current from the switch to the first and second pluralities of nanoparticles.

10. The dry adhesion system of claim 1, wherein the first and second pluralities of nanoparticles are coated with a surface treatment.

11. The dry adhesion system of claim 10, wherein the surface treatment comprises a first layer of nanomagnetic particles and a second layer of shape memory alloy.

12. The dry adhesion system of claim 1, wherein the switch is a button operably connected to a battery or power supply.

13. A dry adhesion system, comprising:
a first plurality of nanoparticles formed on a first substrate and capable of changing from a first shape to a second shape in response to an active stimulus;
a second plurality of nanoparticles formed on a second substrate, wherein the first and second pluralities are configured to entangle to lock the first substrate with the second substrate; and
a switch operably connected to the first substrate and configured to selectively apply the active stimulus, wherein when the switch is activated, the first plurality of nanoparticles change from their respective first shape to their respective second shape to unlock the first substrate from the second substrate.

14. The dry adhesion system of claim 13, wherein the first and second pluralities of nanoparticles are formed from carbon nanotubes.

15. The dry adhesion system of claim 13, wherein the active stimulus is an electric current, temperature gradient, or magnetic field.

16. The dry adhesion system of claim 13, wherein the first plurality of nanoparticles are carbon nanotube hooks in the first shape and carbon nanotube pillars in the second shape.

17. The dry adhesion system of claim 16, wherein the second plurality of nanoparticles are carbon nanotube loops, wherein the hooks and loops are configured to lock the first substrate with the second substrate.

18. The dry adhesion system of claim 17, wherein when the switch is activated the first plurality of nanoparticles change shape from hooks to pillars to release the first substrate from the second substrate.

19. The dry adhesion system of claim 13, wherein the first substrate is attached to a first composite part, and wherein the second substrate is attached to a second composite part.

20. The dry adhesion system of claim 15, wherein electrical wires or electrodes are disposed within the first substrate to selectively apply the electrical current from the switch to the first plurality of nanoparticles.

21. The dry adhesion system of claim 13, wherein the first plurality of nanoparticles is coated with a surface treatment.

22. The dry adhesion system of claim 21, wherein the surface treatment comprises a first layer of nanomagnetic particles and a second layer of shape memory alloy.

23. The dry adhesion system of claim 13, wherein the switch is a button operably connected to a battery or power supply.

24. A method for dry adhesion, comprising:
configuring a first plurality of nanoparticles formed on a first substrate with a second plurality of nanoparticles formed on a second substrate, wherein the first and second pluralities of nanoparticles are capable of changing from a first shape to a second shape in response to an active stimulus;
activating a switch operably connected to the first and second substrates and configured to selectively apply the active stimulus, wherein when the switch is activated, the first and second pluralities of nanoparticles change from their respective first shape to their respective second shape to interlock the first substrate to the second substrate; and
deactivating the switch, wherein when the switch is deactivated, the first and second pluralities of nanoparticles change from their respective second shape to their respective first shape to release the first substrate from the second substrate.

25. The method of claim 24, wherein the first and second pluralities of nanoparticles are formed from carbon nanotubes.

26. The method of claim 24, wherein the active stimulus is an electric current, temperature gradient, or magnetic field.

27. The method of claim 24, wherein the first plurality of nanoparticles are carbon nanotube pillars in the first shape and carbon nanotube hooks in the second shape.

28. The method of claim 27, wherein the second plurality of nanoparticles are carbon nanotube pillars in the first shape and carbon nanotube loops in the second shape.

29. The method of claim 28, wherein when the switch is activated the first and second pluralities of nanoparticles interlock to form a nanoscale hook and loop fastener.

30. A method for reversible and reusable dry adhesion, comprising:
activating a switch configured to selectively apply an active stimulus, wherein the switch is operably connected to a first plurality of nanoparticles formed on a first substrate, wherein the first plurality nanoparticles are capable of changing from a first shape to a second shape in response to the active stimulus, wherein when the switch is activated, the first plurality of nanoparticles change from their respective first shape to their respective second shape to unlock the first plurality of nanoparticles of the first substrate from a second plurality of nanoparticles formed on a second substrate.

31. The method of claim 30, wherein the first and second pluralities of nanoparticles are formed from carbon nanotubes.

32. The method of claim 30, wherein the active stimulus is an electric current, temperature gradient, or magnetic field.

33. The method of claim 30, wherein the first plurality of nanoparticles are carbon nanotube hooks in the first shape and carbon nanotube pillars in the second shape.

34. The method of claim 33, wherein the second plurality of nanoparticles are carbon nanotube loops, wherein the hooks and loops are configured to lock the first substrate with the second substrate.

35. The method of claim 34, when the switch is activated the first plurality of nanoparticles change shape from hooks to pillars to release the first substrate from the second substrate.

36. The method of claim 30, wherein the first plurality of nanoparticles is coated with a surface treatment.

37. The method of claim 36, wherein the surface treatment comprises a first layer of nanomagnetic particles and a second layer of shape memory alloy.
